(19) United States
(12) Patent Application Publication
(10) Pub. No.: US 2004/0214417 A1
(43) Pub. Date: Oct. 28, 2004

(54) Methods of forming tungsten or tungsten containing films

(76) Inventors: Paul Rich, Glos (GB); Stephen Robert Burgess, Gwent (GB); James Francis Edward O'Sullivan, Carfiff (GB); Nicholas Rimmer, Cardiff (GB)

Correspondence Address: VOLENTINE FRANCOS, P.L.L.C., Suite 150, 12200 Sunrise Valley Drive, Reston, VA, 20191, US

(21) Appl. No.: 10/796,274

(22) Filed: Mar. 10, 2004

Related U.S. Application Data
(60) Provisional application No. 60/457,323, filed on Mar. 26, 2003.

(30) Foreign Application Priority Data
Mar. 11, 2003 (GB) 0305544.9

(51) Int. Cl. H01L 21/4763; H01L 21/3205; H01L 21/44

(52) U.S. Cl. 438/592; 438/653; 438/656

(57) ABSTRACT

A method of sputtering a tungsten or tungsten-containing film from a tungsten target onto a semiconductor wafer includes using krypton or xenon as a sputter gas.

The present invention relates to methods of forming tungsten or tungsten-containing film and in particular such methods for use in for producing gate stack layers upon wafers as part of the formation of semiconductor devices. For processing semiconductor devices in the sub-100 nm regime new gate structures with low resistivity to reduce the RC delay are being considered. A particular example under consideration is a polysilicon/tungsten nitride/tungsten gate electrode structure. This structure is attractive because of the much lower resistivity of the W/WN to the prior art WSi or poly-Si, and its ability to withstand subsequent high temperature (e.g. 1000 C.) capacitor anneals required by some memory device technologies. Physical vapour deposition is preferred over chemical vapour deposition because CVD processing results in fluorine contamination.

This proposed structure requires the resistivity of the WN/W layers to be as low as possible and the state of the art know to the inventors is for the sputtered W resistivity to be 11-12 micro ohm cm at a wafer platen temperature of 250 C.

As the bulk resistivity of W is 5.5 micro ohm cm, this suggests that there is scope for improvement and the inventors therefore sought to reduce the resistivity of the sputtered W film further. Argon is almost universally used for the sputtering of metallic layers onto silicon wafers though an improvement in the sputtered layer thickness at the base of high aspect ratio recesses has been reported e.g. in WO 02/053796 of the applicants and EP 1096036. This is achieved by e.g. the reduction of sputter pressure (reduced scattering of sputtered material) possible with some alternative noble gasses to argon and/or where the advantage offered by alternative sputter gasses is the more normal angle of ejection of sputtered material from the surface of the target.

From one aspect the invention consists in a method of sputtering a tungsten or tungsten containing film from a tungsten target onto a semi-conductor wafer including using krypton or xenon as a sputter gas.

As will be gathered from the preamble, the applicants principle interest in this method in this case is producing a field style deposition, rather than the high aspect ratio depositions mentioned above. The adoption of higher atomic weight gasses for these latter depositions is not obvious, because the motivation of achieving an angle of ejection close to 90° is not present in these circumstances and indeed may not be particularly desirable from a uniformity point of view if the surface receiving the deposition is anything other than completely flat.

Preferably the deposition takes place in a vacuum chamber with the krypton pressure of less than 10 mT and it is particularly preferred that the krypton pressure is less than 6 mT.

It is preferred that the resultant resistivity of the tungsten film is less than 11 μohm cm. The power supplied to a target of 330 mm diameter maybe above 3 kW being a power density of about 1 watt cm⁻¹.

The wafer may be placed on a platen during deposition and the platen temperature may be between 200° C. and 400° C. and/or the platen may be negatively DC biased, for example by applying 13.56 MHz RF power to the platen. The broad method set out initially above may be adapted so that the sputtering is reactive sputtering; the sputter gasses include nitrogen and the film deposited in tungsten nitride.

In this case the sputter gasses may further include argon and the ratio of argon to krypton or xenon may be selected to minimize stress in the deposited film.

From another embodiment the invention consists in a method of forming a tungsten/tungsten nitride stack on a wafer including sputtering a tungsten nitride film on a wafer and sputtering a tungsten film on the tungsten nitride film, wherein the two sputtering processes are performed in a single chamber using a single target.

Preferably the wafer is on a platen and the platen temperature is maintained substantially the same for the two sputter processes.

Conveniently the tungsten film may be sputtered using a method as defined above and/or the tungsten nitride film may be deposited using a method as defined above or the sputter gas in that last case may be entirely argon.

The invention includes forming a gate structure using the stack forming methods defined above.

From another aspect the invention therefore consists in a method of using krypton in the sputtering of tungsten nitride and tungsten onto a substrate surface without recesses wherein the sputtering of the WN and W is performed in the same chamber using a single tungsten target. One application of such a method is the sputtering of a gate stack onto a polysilicon surface on a silicon wafer e.g. for the formation of a memory device, and the invention includes such a stack.

Although the invention has been defined above it is to be understood that it includes any inventive combination of the features set out above or in the following description.

The invention may be performed in various ways and its specific embodiment will be described with reference to the accompanying drawings in which:

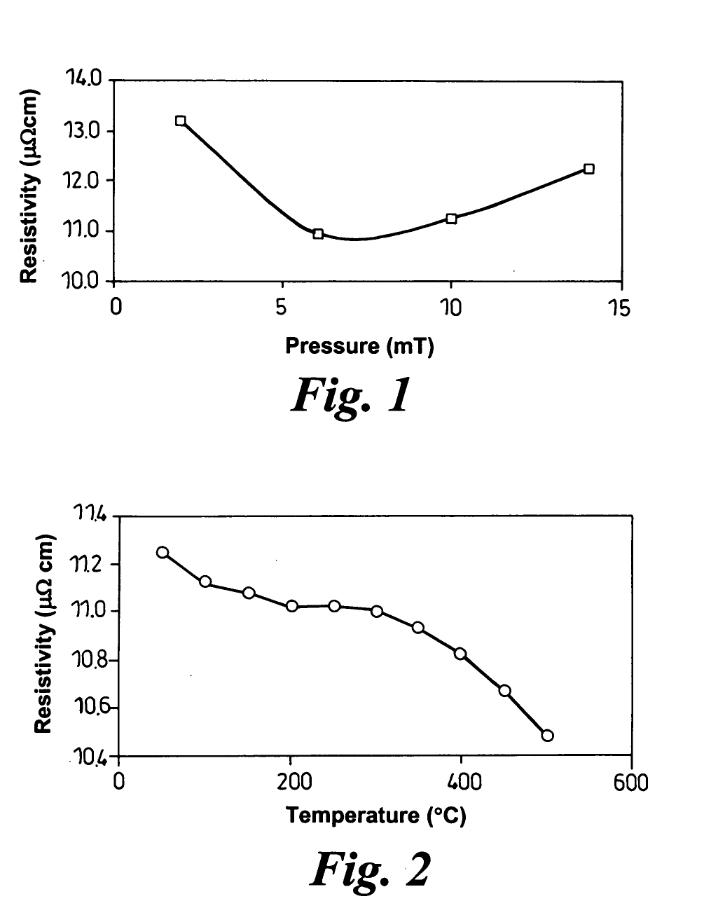

FIG. 1 shows the resistivity of a sputtered tungsten film against argon pressure for particular deposition conditions;

FIG. 2 shows the resistivity of a sputtered tungsten film with respect to platen temperature, with the conditions otherwise as in FIG. 1;

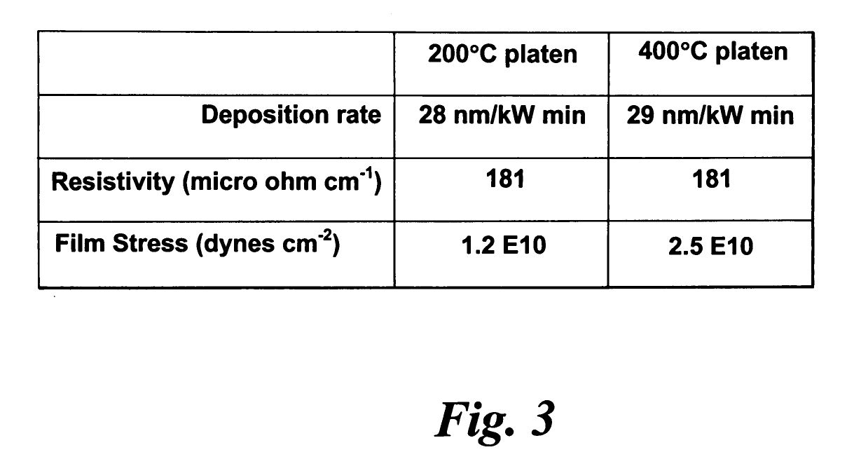

FIG. 3 is a table giving film characteristics for a tungsten nitride film deposited respectively at 200° C. and 400° using a mixture of argon and nitrogen;

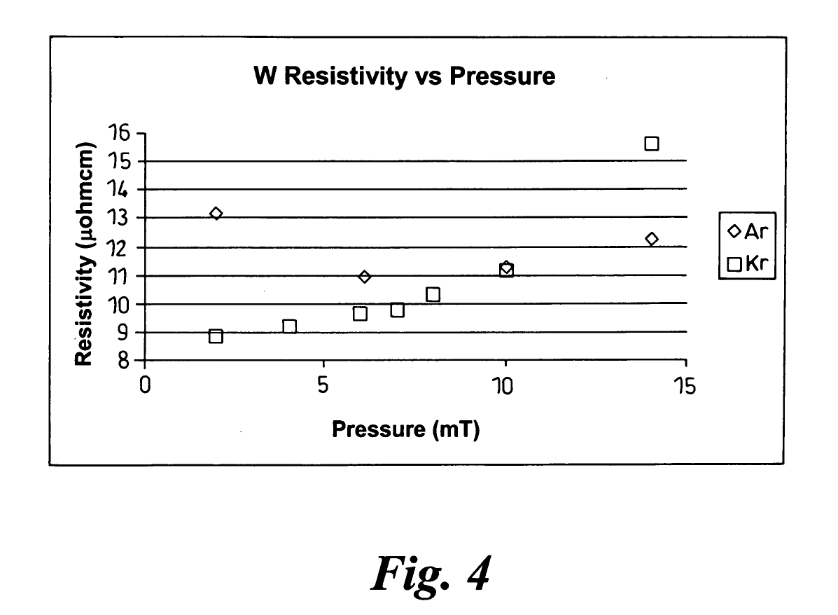

FIG. 4 is a plot of resistivity against pressure for films deposited by argon and krypton respectively;

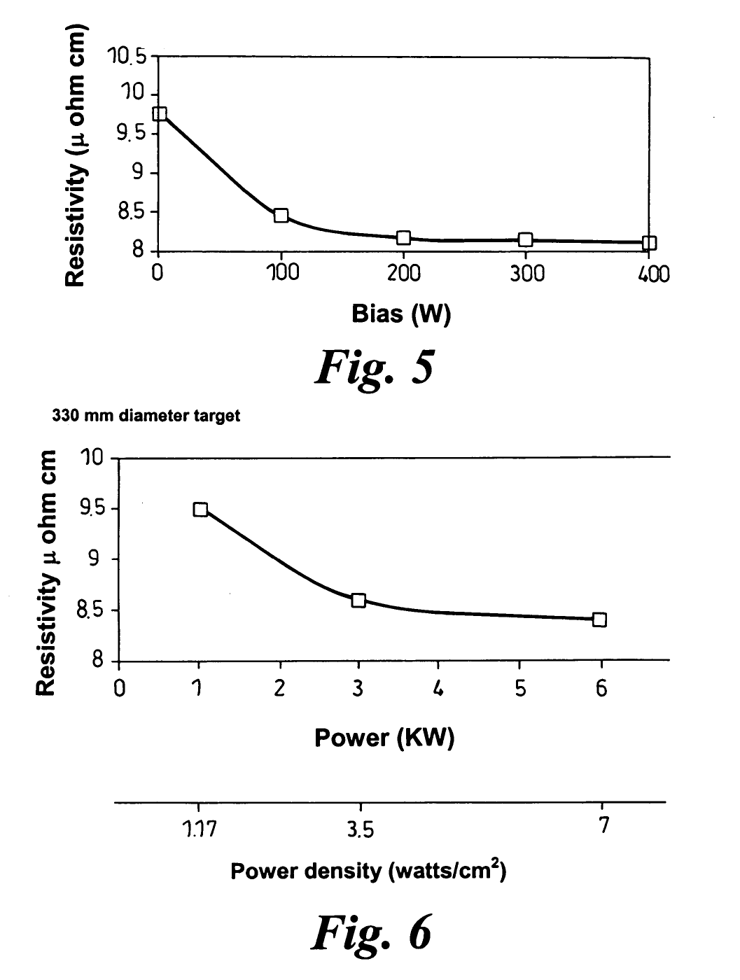

FIG. 5 is a graph illustrating the variation in resistivity with platen bias during krypton induced deposition;

FIG. 6 is a corresponding graph for resistivity against power, with no bias voltage; and

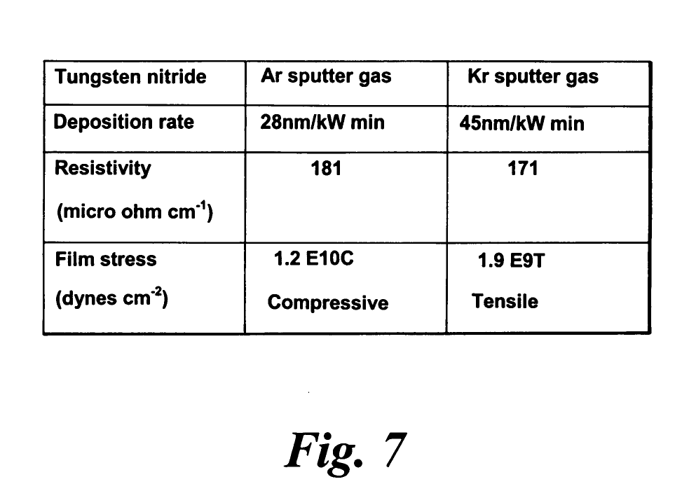

FIG. 7 compares film characteristics for a tungsten nitride film deposited using argon and krypton respectively.

The sputtering system used for this process was a Trikon Technologies Inc. Sigma® fxp® single wafer multi-chamber cluster sputter tool where wafers are placed singly onto a heated platen face up opposing a fixed target with a moving magnetron behind.

The wafers are transported from atmosphere to vacuum and are then transported under vacuum into a pre-clean chamber where they are degassed. Typically they may be sputter cleaned. They are then transported under vacuum to a deposition chamber where they are placed upon the platen. It should be understood that there is a strong commercial advantage in being able to deposit both the WN and W layers in the same process chamber. This therefore requires that the platen temperature and target are the same for both processes as it is impracticable to change temperature or target without making the chamber significantly more complex, thus losing the advantage of simplicity, space and cost from carrying out the two processes in the same chamber. The WN is thereby formed by reactive sputtering, where nitrogen is added to the noble sputter gas to form the nitride from the metal target. A process platen temperature is selected as a compromise for the two processes and as appropriate for the processes.

150 mm silicon wafers were used for the experiments and a 99.999% pure W target supplied by Honeywell was used for the sputtering. Sheet resistivity was measure by an automatic 4 point probe and thickness measured by electron microscope observation of cleaved wafers. All wafers were outgassed in a separate module for 2 minutes with 2 kW applied to a heater lamp.

FIG. 1 shows resistivity of sputtered tungsten with respect to argon pressure at 1 kw of applied power and a 200° C. platen temperature (no wafer clamping). The argon gas was supplied at 200 sccm. As can be seen there is a significant effect of pressure on resistivity, with a minima achieved at around 6 millitorr. This observation of a minima in resistivity with both higher and lower pressures yielding higher resistivity is well known with the literature offering various competing explanations as to why.

FIG. 2 shows resistivity of sputtered tungsten with respect to platen temperature with process conditions as for FIG. 1 at an argon pressure of 6 millitorr. As is usual for metals resistivity drops with increasing deposition temperature. The temperatures given in the figure are of the platen with the wafer unclamped. In a steady state without sputtering a platen temperature of 400° C. gives a silicon wafer temperature of approximately 280° C. where there is no significant gas conduction e.g. at a pressure of less than say 50 millitorr. No substrate bias voltage was applied.

Thin films of tungsten nitride deposited at platen temperature of 200° C. and 400° C. have broadly the same characteristics. Results are given in FIG. 3 for a process of 38 seconds of preheat, 1 kw of applied power and 60 sccm of argon and 70 sccm of nitrogen.

It has been found that substituting krypton for argon significantly reduces the resistivity of the sputtered tungsten, whilst using the same target and target power supply, pumping system, platen temperature and target to substrate distance.

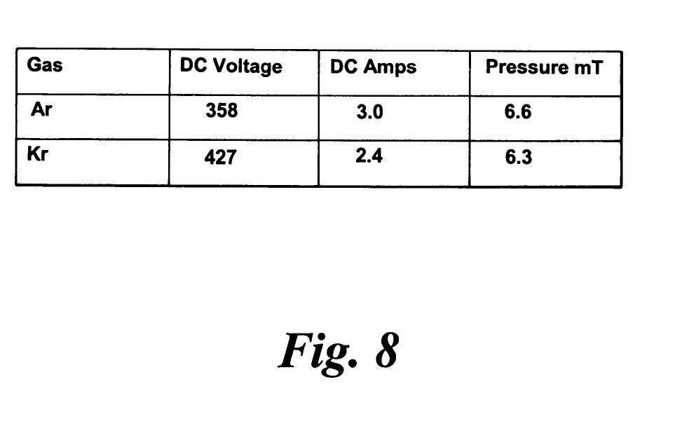

In FIG. 4 can be seen resistivity of tungsten for both argon and krypton with respect to pressure. The sputtering was at 1 kW of applied power to the target with no substrate bias voltage. For the same applied power, the sputter rate was higher, the target voltage was higher and the target current was lower as is shown in FIG. 8. Krypton deposited tungsten at 84 nm per Kw/minute compared to 65 nm per kW/minute for argon. As can be seen from FIG. 4, down to about 10 millitorr krypton and argon deposit tungsten of the same resistivity. Below about 10 millitorr there are pressures at which krypton deposits lower resistivity tungsten than argon. Further experiments are expected to reveal that there is a minimal to the resistivity of tungsten sputtered by krypton, with lower pressures producing higher resistivity films. Above 10 millitorr it is interesting to note that it is argon that deposits lower resistivity tungsten than krypton as can be seen at the data points at 14 millitorr where tungsten resistivity is 12.27 micro ohm cm for argon and 15.6 micro ohm cm for krypton. Applying substrate bias voltage by applying 13.56 MHz RF power to the platen reduces resistivity for both argon and krypton. The results shown in FIG. 5 are for krypton at 7 millitorr pressure.

Increased target power reduces sputtered tungsten resistivity for krypton, whilst it increases resistivity with argon. FIG. 6 shows the effect of target power on resistivity for krypton at 2 millitorr with no bias voltage applied to the substrate. As can be seen a resistivity of about 8.5 micro ohm cm is achieved, without bias. Further experiments are planned with bias and higher target power levels and also reduced sputtering pressures.

It should be understood that as these are very thin layers it is not always practicable to increase target power density as deposition films may become impracticably short to control precisely.

Krypton was then substituted for argon in the tungsten nitride process with 1 kw of power applied to the target and 60 sccm of argon or krypton and 70 sccm of nitrogen and the results are shown in FIG. 7. As can be seen there is a strong effect on film stress, indicating a different film structure which may influence barrier performance and stability.

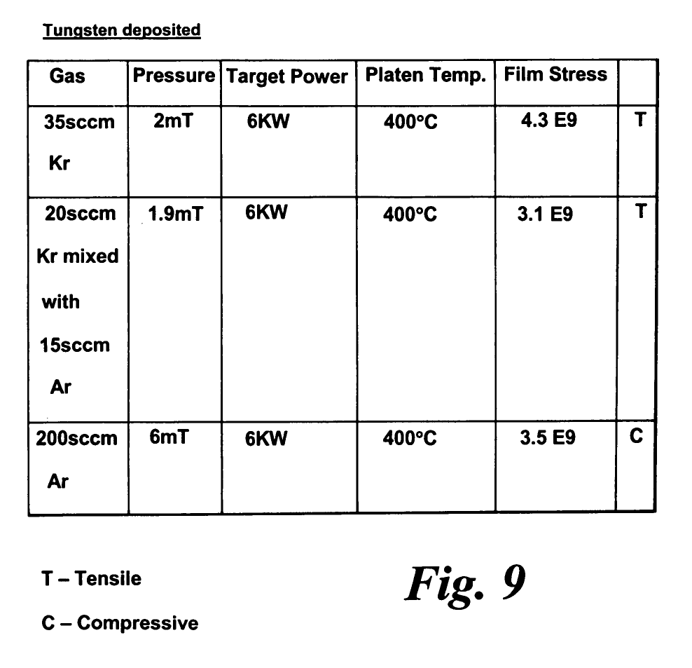

It is therefore clearly possible to mix argon and krypton with the nitrogen to form tungsten nitride barriers with specific stress characteristics, e.g. nominally zero. Different mixtures of argon and krypton ranging from 0% to 100% may be used for the two processes in the same chamber. FIG. 9 shows the effect of changing the sputter gas on the stress of a tungsten film. The gas flows of Argon and krypton selected are those that yield lowest resistivity. As can be seen the film stress may be changed from c9ompressive to tensile by changing from argon to krypton, again indicating a possibility of depositing a zero stress film. Further improvements in resistivity of tungsten may be achieved by using xenon or xenon mixtures, xenon having a significantly higher molar mass than krypton and argon.

1. A method of sputtering a tungsten or tungsten-containing film from a tungsten target onto a semiconductor wafer including using krypton or xenon as a sputter gas.

2. A method as claimed in claim 1 wherein the deposition takes place in a vacuum chamber with a krypton pressure of less than 10 mT.

3. A method as claimed in claim 2 wherein krypton pressure is less than 6 mT.

4. A method as claimed in claim 1 wherein the resistivity of the tungsten film is less than 11 μohm cm.

5. A method as claimed in claim 1 wherein the power supplied to the target is greater than about 1 watt per cm.

6. A method as claimed in claim 1 wherein the wafer is placed on a platen during deposition and the platen temperature is between 200° C. and 400° C.

7. A method as claimed in claim 1 wherein the platen is negatively DC biased.

8. A method as claimed in claim 1 wherein the sputtering is reactive sputtering; the sputter gases includes nitrogen and the film deposited is tungsten nitride.

9. A method as claimed in claims claim 1 wherein the sputter gasses further include argon.

10. A method as claimed in claim 9 wherein the ratio of argon to krypton or xenon is selected to minimise stress in the deposited film.

11. A method of forming a tungsten/tungsten nitride stack on a wafer including sputtering a tungsten nitride film on a wafer and sputtering a tungsten film on the tungsten/nitride film wherein the two sputtering processes are performed in a single chamber using a single target.

12. A method as claimed in claim 11 wherein the wafer is on a platen and the platen temperature is maintained substantially the same for the two sputter processes.

13. A method as claimed in claim 11 wherein the tungsten film is sputtered using a method as claimed in claim 1.

14. A method as claimed in claim 11 wherein the tungsten or tungsten containing film is deposited using the method of claim 8.

15. A gate structure formed by the claim 11.
